(19) United States
(12) Patent Application Publication
(10) Pub. No.: US 2026/0146318 A1
(43) Pub. Date: May 28, 2026

(54) METHODS AND SYSTEMS FOR LINE PURGING

(71) Applicant: ASM IP Holding B.V., Almere (NL)

(72) Inventors: Matthew Surman, Helsinki (FI); Leo Lukose, Leuven (BE)

(21) Appl. No.: 18/924,526

(22) Filed: Oct. 23, 2024

Related U.S. Application Data
(60) Provisional application No. 63/545,655, filed on Oct. 25, 2023.

(51) Int. Cl. C23C 16/44; C23C 16/455; C23C 16/50; C23C 16/52

(52) U.S. Cl. CPC C23C 16/4408; C23C 16/45565; C23C 16/50; C23C 16/52

(57) ABSTRACT

Methods for purging in deposition apparatuses and related systems are disclosed. Embodiments of the present disclosure comprise measuring a precursor residual concentration in a exhaust gas stream and ending a purge when the concentration of the precursor residuals in the exhaust gas stream is at or below the reference precursor residual concentration.

### CROSS-REFERENCE TO RELATED APPLICATION(S)

This Application claims the benefit of U.S. Provisional Application 63/545,655 filed on Oct. 25, 2023, the entire contents of which are incorporated herein by reference.

### FIELD OF INVENTION

The present disclosure is in the field of semiconductor deposition equipment, and in the field of preventive maintenance thereof.

### BACKGROUND OF THE DISCLOSURE

In precursor-consuming machines such as semiconductor deposition equipment, precursor lines need regular purging, for example during preventive maintenance. Substantially complete precursor removal during preventive maintenance can be of paramount importance for safety reasons. Unfortunately, substantially complete precursor removal can take a lot of time. Therefore, there is a need for methods and systems that allow faster precursor purging from lines.

### SUMMARY OF THE DISCLOSURE

Described herein is a deposition apparatus comprising a precursor delivery system constructed and arranged to receive a precursor source comprising a precursor; a reaction chamber, the reaction chamber being fluidly connected to the precursor source by a precursor line to provide the precursor from the precursor source to the reaction chamber; a purge gas delivery system constructed and arranged for operationally coupling to a purge gas source comprising a purge gas, the purge gas source being constructed and arranged to provide purge gas stream to at least one of the reaction chamber and the precursor line; an exhaust line constructed and arranged to receive an exhaust gas stream from at least one of the precursor line and the reaction chamber, the exhaust gas stream comprising the precursor and the purge gas; a residual gas analyzer constructed and arranged to measure a concentration of the precursor in the exhaust gas stream; and, a controller comprising a memory comprising computer-readable instructions which, when executed, cause the system to start a purge at a pre-determined purge start time, the purge comprising providing the purge gas stream to at least one of the reaction chamber and the precursor line; compare the concentration of the precursor in the exhaust gas stream to a reference precursor concentration; continue the purge when the concentration of the precursor in the exhaust gas stream exceeds the reference precursor concentration; and, end the purge when the concentration of the precursor in the exhaust gas stream is at or below the reference precursor concentration.

In some embodiments, the precursor comprises a metal.

In some embodiments, the precursor comprises an element selected from Si, Ge, Sn, Se, and Te.

In some embodiments, the precursor comprises a halide.

In some embodiments, the precursor comprises one or more ligands.

In some embodiments, the one or more ligands are selected from the list consisting of alkyls, alkenyls, aryls, dienyls, amines, amides, and beta-diketonates.

In some embodiments, the precursor comprises a pnictogen hydride.

In some embodiments, the reaction chamber comprises a showerhead injector and a substrate support.

In some embodiments, the system comprises a plasma source, in which case the system can be constructed and arranged for contacting the substrate with one or more reactive species, the one or more reactive species including at least one of ions and radicals.

Further described herein is a method of purging in a deposition apparatus, the method comprising providing a purge gas stream to at least one of a reaction chamber and a precursor line, thereby removing precursor residuals from at least one of the reaction chamber and the precursor line; removing a exhaust gas stream from at least one of the reaction chamber and the precursor line by means of an exhaust line, the exhaust gas stream comprising the purge gas stream and the precursor residuals; measuring, by means of a residual gas analyzer, a precursor residual concentration in the exhaust gas stream; comparing, by means of a controller, the precursor residual concentration in the exhaust gas stream to a reference precursor residual concentration; continuing with providing the purge gas stream when the concentration of the precursor residual in the exhaust gas stream exceeds the reference precursor residual concentration; and, ending the provision of the purge gas stream when the concentration of the precursor residuals in the exhaust gas stream is at or below the reference precursor residual concentration.

In some embodiments, the purge gas stream comprises one or more inert gasses.

In some embodiments, the one or more inert gasses comprise one or more of N2 and a noble gas.

In some embodiments, the noble gas comprises argon.

In some embodiments, the purge gas stream comprises one or more reactive gasses.

In some embodiments, the one or more reactive gasses comprise oxygen.

In some embodiments, the precursor residuals comprise one or more substances selected from precursors, ligands, reaction products, and combustion products.

In some embodiments, the precursor residuals comprise one or more of CO2, CH4, and HCl.

Further described herein is a method of switching a precursor vessel in a deposition apparatus comprising, closing off a used precursor vessel from a precursor line comprised in the system using a precursor vessel valve, the precursor line being in fluid connection with a reaction chamber comprised in the system; purging at least one of the precursor line and the reaction chamber by means of a method as described herein; removing the used precursor vessel from the system; and, installing a new precursor vessel in the system.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1, 2, and 4 illustrate embodiments of methods as described herein.

FIG. 3 illustrates an embodiment of a system as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Semiconductor deposition equipment is becoming increasingly complex. With this complexity comes regular maintenance. One maintenance action which can be a regular occurrence is precursor vessel change, in which a depleted precursor vessel is decoupled and a new precursor vessel is installed. Such precursor vessel changes can take a lot of time because of the need for removal of precursors and other hazardous species from precursor lines to allow safe precursor vessel change. Embodiments of the presently disclosed subject matter enable fast and safe precursor vessel change.

Surface-limited deposition processes such as atomic layer deposition comprise many purge steps. Those purge steps take time and employ a large flow rate of purge gasses. It would be desirable to reduce purge time to lower purge gas consumption. Embodiments of the presently disclosed subject matter enable reduced purge gas consumption.

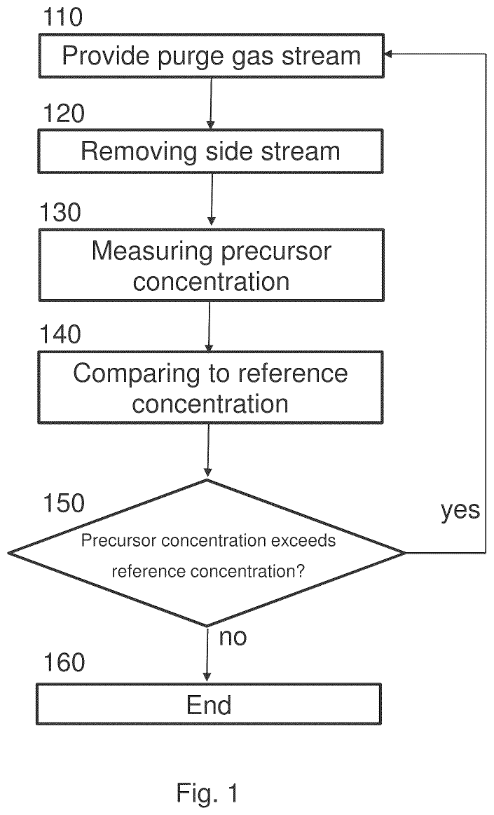

Referring to FIG. 1, described herein is a method of purging in a deposition apparatus, such as in a semiconductor deposition apparatus. The method comprises providing 110 a purge gas stream. The purge gas stream can be provided to a reaction chamber, to a precursor line, or to both. Thus, precursor residuals can be removed from the reaction chamber, from the precursor line, or from both. In some embodiments, the precursor residuals comprise one or more of precursor vapors, particulate matter, and physisorbed precursor. Upon taking up or entraining the precursor residuals, the purge gas can form a exhaust gas stream which can be removed 120 from the apparatus, e.g. from the reaction chamber, from the precursor line, or both. For example, the exhaust gas stream can be removed by means of an exhaust line. The method of FIG. 1 further comprises measuring 130 a precursor concentration in the exhaust gas stream by means of a residual gas analyzer. The method of FIG. 1 further comprises comparing 140 the precursor concentration in the exhaust gas stream to a reference precursor concentration. The method of FIG. 1 further comprises evaluating 150 whether or not the precursor concentration in the exhaust gas stream exceeds the reference precursor concentration, or not. In case the concentration of the precursor in the exhaust gas stream exceeds the reference precursor concentration, the method of FIG. 1 comprises continuing with providing 110 the purge gas stream. In case the concertation of the precursor in the exhaust gas stream is at or below the reference precursor concentration, the method of FIG. 1 comprises ending the provision of the purge gas stream, upon which the method ends 160.

For example, the reference precursor concentration can be at the detection limit of the residual gas analyzer, or at 150% of the detection limit of the residual gas analyzer, or at 300% of the detection limit of the residual gas analyzer, or at another suitable value. It shall be noted that residual gas analyzers include gas detectors, such as mass spectrometers and Fourier transform infrared spectrometers which, as such, are known in the art.

A method according to the embodiment of FIG. 1 can be advantageously employed during maintenance, e.g. during scheduled or unscheduled maintenance. Indeed, by purging only for as long as needed, maintenance time can be minimized.

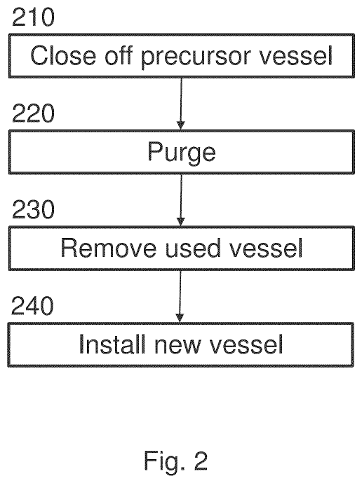

Thus, with reference to FIG. 2, further described herein is a method of switching a precursor vessel in a deposition apparatus. The method comprises closing off 210 a used precursor vessel from a precursor line comprised in the system, e.g. using a precursor vessel valve. The precursor line can be in fluid connection with a reaction chamber comprised in the system. The method of FIG. 2 further comprises purging 220 at least one of the precursor line and the reaction chamber by means of a method as described herein. The method of FIG. 2 further comprises removing 230 the used precursor vessel from the system. The method of FIG. 2 further comprises installing 240 a new precursor vessel in the system. Thus, purge time and consequently maintenance time can be minimized.

A method according to the embodiment of FIG. 1 can be advantageously employed during an atomic layer deposition process, i.e. to dynamically adapt purge time during a process. Thus, purge time, and consequently process duration, can be minimized. Additionally or alternatively, process drift can be minimized. Indeed, by cross-referencing film properties and exhaust gas content during purges, it can be inferred how much purging is needed in terms of by-product content in the exhaust gas. Once that value is known it can be employed as a reference value in a feedback loop, such that it can be used to dynamically control purge times to make processing times and process gas consumption as efficient as possible.

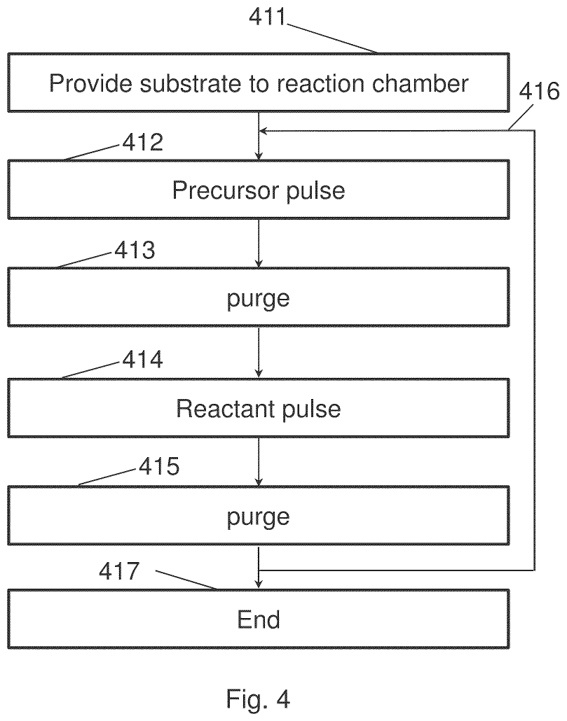

An embodiment of an atomic layer deposition process is illustrated with the aid of FIG. 4. The method comprises a step 411 of positioning a substrate on a substrate support comprised in a reaction chamber. Then, the method comprises a cyclical vapor phase deposition process 416 that comprises repeatedly executing a plurality of cycles. Ones from the plurality of cycles comprise a precursor pulse 412 and a reactant pulse 414. Subsequent precursor pulses 412 and reactant pulses 414 are separated by purges 413,415 to prevent gas phase mixing between precursor and reactant. The reactant pulses comprise exposing the substrate to a reactant, such as an oxygen reactant such as oxygen or a nitrogen reactant such as ammonia. The precursor pulses comprise exposing the substrate to a precursor, such as a metal precursor. The cyclical deposition process 416 can be carried out until a material having a desired thickness has been deposited. After a material having a desired thickness has been deposited, the method ends 417. Of course, one or more of the cycles can optionally comprise further pulses such as one or more further precursor pulses and one or more further reactant pulses which, in turn, can be separated from other reactant and precursor pulses by purges.

In some embodiments, the precursor residuals comprise one or more substances selected from precursors, ligands, reaction products, and combustion products.

In some embodiments, the precursor residuals comprise one or more of CO₂, CH₄, and HCl.

Ligands can comprise alkanes, alkenes, aromatic compounds, amines, amides, and beta-diketones, amongst others.

In some embodiments, the precursor residuals comprise one or more combustion products such as nitrogen oxides, CO₂, and H₂O.

Precursors as such are known in the art and include metal precursors such as transition metal precursors, rare earth metal precursors, and post transition metal precursors. The precursors can comprise alkyls, alkenyls, aryls, amines, amides, metal-pi complexes, amidinates, and beta-diketonates, amongst others.

In some embodiments, the precursor comprises a metal.

In some embodiments, the precursor comprises an element selected from Si, Ge, Sn, Se, and Te.

In some embodiments, the precursor comprises a halide.

In some embodiments, the precursor comprises one or more ligands. In some embodiments, the one or more ligands are selected from the list consisting of alkyls, alkenyls, aryls, dienyls, amines, amides, and beta-diketonates.

In some embodiments, the precursor comprises a pnictogen hydride. Suitable pnictogen hydrides can include phosphine and arsine.

In some embodiments, the purge gas stream comprises one or more inert gasses. Suitable inert gasses can include one or more of N₂ and a noble gas. Suitable noble gasses can be selected from helium, neon, argon, krypton, and xenon.

In some embodiments, the one or more inert gasses comprise one or more of N₂ and a noble gas. In some embodiments, the noble gas is selected from He, Ne, Ar, Kr, and Xe. In some embodiments, the noble gas comprises argon.

In some embodiments, the purge gas stream comprises one or more reactive gasses. In some embodiments, the one or more reactive gasses are selected from oxygen, halogen, nitrogen, radicals, carbon reactants. In some embodiments, the one or more reactive gasses are capable of at least partially volatilizing and/or entraining the precursor residuals by reacting with them.

In some embodiments, the one or more reactive gasses comprise oxygen.

In some embodiments, the purge gas comprises an oxygen species. The oxygen species can be selected from H₂O, O₂, and O₃.

In some embodiments, the purge gas comprises a halogen. Suitable halogens include fluorine, chlorine, bromine, and iodine.

In some embodiments, the purge gas comprises a nitrogen species such as ammonia or hydrazine or an alkyl-substituted hydrazine derivative.

In some embodiments, the purge gas comprises radicals such as hydrogen radicals, oxygen radicals, or nitrogen radicals.

In some embodiments, the purge gas comprises a carbon reactant such as methane.

Presently described methods of purging in a semiconductor deposition apparatus can be advantageously employed to speed up replacement of empty precursor vessels. Thus, described herein is a method of switching a precursor vessel in a deposition apparatus. The method comprises closing off a used precursor vessel from a precursor line comprised in the system using a precursor vessel valve. The precursor line is in fluid connection with a reaction chamber comprised in the system. The method further comprises purging at least one of the precursor line and the reaction chamber by means of a method as described herein. After purging has completed, the method further comprises removing the used precursor vessel from the system and installing a new precursor vessel in the system.

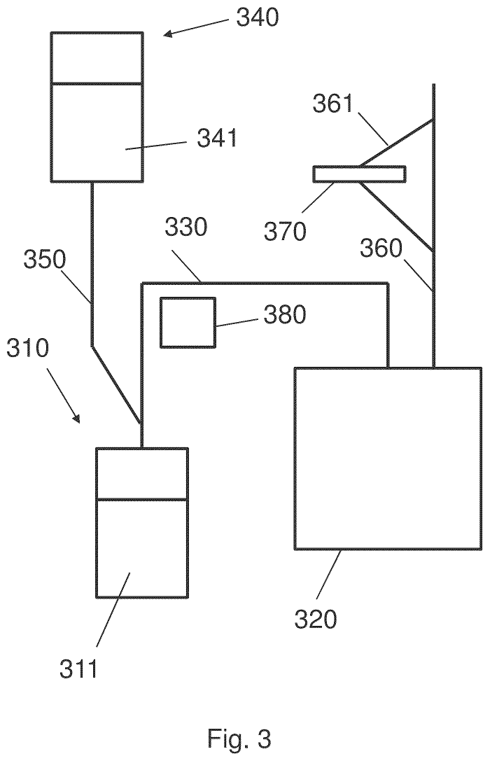

Further described herein, and with reference to FIG. 3, is an embodiment of a deposition apparatus. The deposition apparatus comprises a precursor source 310. The precursor source 310 can be operationally connected to a precursor delivery system constructed and arranged to receive the precursor source 310. The precursor source 310 comprises a precursor 311. Some suitable precursors 311 are described elsewhere herein. The deposition apparatus further comprises a reaction chamber 320. The reaction chamber 320 can comprise, for example, an atomic layer deposition reaction chamber or a chemical vapor deposition reaction chamber. In some embodiments (not shown), the reaction chamber comprises a showerhead injector and a substrate support. For example, the deposition apparatus can further comprise a plasma source (not shown) that is constructed and arranged for generating a plasma. Active species such as ions and radicals can be generated in the plasma. A substrate, when comprised in the reaction chamber 320, can be contacted with the active species. The reaction chamber 320 is fluidly connected to the precursor source 310 by a precursor line 330 to provide the precursor 311 from the precursor source 310 to the reaction chamber 320. The deposition apparatus further comprises a purge gas delivery system, e.g. comprising purge line 350, constructed and arranged for operationally coupling to a purge gas source 340. The purge gas source 340 further comprises a purge gas 341. As illustrated, the purge gas source 340 is constructed and arranged to provide a purge gas stream to the precursor line 330. Additionally or alternatively, the purge gas source 340 can be constructed and arranged to provide a purge gas stream to the reaction chamber 320. For example, the purge gas source 340 can be connected to the precursor line 330 by means of a purge line 350. The deposition apparatus further comprises an exhaust line 360. The exhaust line 360 is constructed and arranged to receive an exhaust gas stream from at least one of the precursor line 330 and the reaction chamber 320. In the embodiment shown, the exhaust line 360 is fluidly connected to the reaction chamber 320. In some embodiments (not shown), the exhaust line 360 is fluidly connected to the precursor line 350. In some embodiments (not shown), the exhaust line 360 is fluidly connected to the reaction chamber 320 and to the precursor line 350.

The deposition apparatus further comprises a residual gas analyzer 370. The residual gas analyzer 370 is constructed and arranged to measure a concentration of the precursor in the exhaust gas stream. In some embodiments (not shown), the residual gas analyzer is comprised in the exhaust line 360. In some embodiments (shown), the residual gas analyzer 370 is comprised in a bypass 361 that branches off from the exhaust line 360.

The deposition apparatus further comprises a controller 380. The controller can comprise a memory that can comprise computer-readable instructions which, when executed, cause the system to start a purge at a pre-determined purge start time, the purge comprising providing the purge gas stream to at least one of the reaction chamber and the precursor line; compare the concentration of the precursor in the exhaust gas stream to a reference precursor concentration; continue the purge when the concentration of the precursor in the exhaust gas stream exceeds the reference precursor concentration; and, end the purge when the concentration of the precursor in the exhaust gas stream is at or below the reference precursor concentration.

In some embodiments, a deposition apparatus as described herein can further comprise a plasma source. Suitable plasma sources include capacitive plasma sources, microwave plasma sources, and inductively coupled plasma sources. In some embodiments, the system is constructed and arranged for contacting the substrate with one or more reactive species. The one or more reactive species can include at least one of ions and radicals. Ions and radicals can be particularly generated in a plasma.

1. A deposition apparatus comprising:
a precursor delivery system constructed and arranged to receive a precursor source comprising a precursor;
a reaction chamber, the reaction chamber being fluidly connected to the precursor source by a precursor line to provide the precursor from the precursor source to the reaction chamber;
a purge gas delivery system constructed and arranged for operational coupling to a purge gas source comprising a purge gas, the purge gas source being constructed and arranged to provide purge gas stream to at least one of the reaction chamber and the precursor line;
an exhaust line constructed and arranged to receive an exhaust gas stream from at least one of the precursor line and the reaction chamber, the exhaust gas stream comprising the precursor and the purge gas;
a residual gas analyzer constructed and arranged to measure a concentration of the precursor in the exhaust gas stream; and
a controller comprising a memory comprising computer-readable instructions which, when executed, cause the apparatus to:
start a purge at a pre-determined purge start time, the purge comprising providing the purge gas stream to at least one of the reaction chamber and the precursor line;
compare the concentration of the precursor in the exhaust gas stream to a reference precursor concentration;
continue the purge when the concentration of the precursor in the exhaust gas stream exceeds the reference precursor concentration; and
end the purge when the concentration of the precursor in the exhaust gas stream is at or below the reference precursor concentration.

2. The apparatus according to claim 1, wherein the precursor comprises a metal.

3. The apparatus according to claim 1, wherein the precursor comprises an element selected from Si, Ge, Sn, Se, and Te.

4. The apparatus according to claim 1, wherein the precursor comprises a halide.

5. The apparatus according to claim 1, wherein the precursor comprises one or more ligands.

6. The apparatus according to claim 5, wherein the one or more ligands are selected from a list consisting of alkyls, alkenyls, aryls, dienyls, amines, amides, and beta-diketonates.

7. The apparatus according to claim 1, wherein the precursor comprises a pnictogen hydride.

8. The apparatus according to claim 1, herein the reaction chamber comprises a showerhead injector and a substrate support.

9. The apparatus according to claim 1, further comprising a plasma source, wherein the apparatus is constructed and arranged for contacting a substrate with one or more reactive species, the one or more reactive species including at least one of ions and radicals.

10. A method of purging in a deposition apparatus, the method comprising
providing a purge gas stream to at least one of a reaction chamber and a precursor line, thereby removing precursor residuals from at least one of the reaction chamber and the precursor line;
removing an exhaust gas stream from at least one of the reaction chamber and the precursor line by an exhaust line, the exhaust gas stream comprising the purge gas stream and the precursor residuals;
measuring, by a residual gas analyzer, a precursor residual concentration in the exhaust gas stream;
comparing, by a controller, the precursor residual concentration in the exhaust gas stream to a reference precursor residual concentration;
continuing with providing the purge gas stream when the precursor residual concentration in the exhaust gas stream exceeds the reference precursor residual concentration; and,
ending the provision of the purge gas stream when the precursor residual concentration of the precursor residuals in the exhaust gas stream is at or below the reference precursor residual concentration.

11. The method according to claim 10, wherein the purge gas stream comprises one or more inert gasses.

12. The method according to claim 11, wherein the one or more inert gasses comprise one or more of N₂ and a noble gas.

13. The method according to claim 12, wherein the noble gas comprises argon.

14. The method according to claim 10, wherein the purge gas stream comprises one or more reactive gasses.

15. The method according to claim 14, wherein the one or more reactive gasses comprise oxygen.

16. The method according to claim 10, wherein the precursor residuals comprise one or more substances selected from precursors, ligands, reaction products, and combustion products.

17. The method according to claim 16, wherein the precursor residuals comprise one or more of CO₂, CH₄, and HCl.

18. A method of switching a precursor vessel in a deposition apparatus comprising,
closing off a used precursor vessel from a precursor line comprised in a system using a precursor vessel valve, the precursor line being in fluid connection with a reaction chamber comprised in the system;
purging at least one of the precursor line and the reaction chamber by a method according to claim 10;
removing the used precursor vessel from the system; and,
installing a new precursor vessel in the system.
